(19) United States
(12) Patent Application Publication
(10) Pub. No.: US 2009/0191703 A1
(43) Pub. Date: Jul. 30, 2009

(54) PROCESS WITH SATURATION AT LOW ETCH AMOUNT FOR HIGH CONTACT BOTTOM CLEANING EFFICIENCY FOR CHEMICAL DRY CLEAN PROCESS

(75) Inventors: Xinliang Lu, Fremont, CA (US); Haichun Yang, Santa Clara, CA (US); Zhenbin Ge, San Jose, CA (US); Chien-Teh Kao, Sunnyvale, CA (US); Mei Chang, Saratoga, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC.

(21) Appl. No.: 12/021,844

(22) Filed: Jan. 29, 2008

(51) Int. Cl. H01L 21/4763; H01L 21/302

(52) U.S. Cl. 438/637; 438/706; 257/E21.214; 257/E21.495

(57) ABSTRACT

A method for removing oxides from the bottom surface of a contact hole is provided. The method provides efficient cleaning of the bottom surface without distortion of the contact hole upper and sidewall surfaces.

### BACKGROUND OF THE INVENTION

1. Field of the Invention

Embodiments of the present invention generally relate to methods for forming electronic devices. More particularly, embodiments of the present invention generally relate to methods for cleaning contact hole bottom surfaces in the formation of electronic devices.

2. Description of the Related Art

In the fabrication of an active electronic device, such as a Metal Oxide Silicon Field Effect Transistor (“MOSFET”), the electrodes and interconnecting pathways include silicide layers formed by depositing a refractory metal on bare silicon and annealing the layer to produce the metal silicide layer. A dielectric layer is then deposited over the metal silicide, and a contact hole is formed through the dielectric layer to the surface of the metal silicide. The contact hole is then filled with a bulk metal to complete the contact.

In a typical fabrication process, the metal silicide may be formed on a substrate in one vacuum environment and, after contact hole formation, transferred to another vacuum environment for further processing. As a result, a native oxide may develop on the contact hole bottom surface. The cleanliness of the contact hole bottom surface is critical for reducing contact resistance and ensuring optimal device performance. Therefore, the contact hole bottom surface must be cleaned and the native oxide removed prior to further processing.

Sputter etch processes have been used in an attempt to clean contact hole bottom surfaces; however, such techniques may damage the underlying surface. Sputter etch techniques may also alter the contact hole geometry due to the physical bombardment of ions on the surface surrounding the contact hole. For example, the contact opening may become widened or tapered, often referred to as “faceting.”

A more recent approach to remove native oxide films involves forming a fluorine/silicon-containing salt on the substrate surface that is subsequently removed by thermal anneal. According to this approach, a thin layer of the salt is formed by reacting a fluorine-containing gas with the oxide surface. The salt is then heated to an elevated temperature sufficient to dissociate the salt into volatile by-products, which are then removed from the processing chamber.

However, during this process, the upper and sidewall surfaces of the contact opening are exposed to the oxide cleaning chemicals for a longer period of time than the bottom contact oxide surface. Prior art recipes etch the upper and sidewall surfaces more than the bottom contact surface during this time period. This results in significantly lower oxide removal at the contact hole bottom surface than at the upper and sidewall surfaces; hence, the contact hole bottom surface cleaning efficiency is very low. Accordingly, the contact resistance may be elevated, resulting in inefficiency of the device, and/or the geometry of the contact opening may be compromised, resulting in current leakage.

Therefore, a need exists for a dry clean process that removes oxides from a bottom surface of a contact hole with increased efficiency without over etching the upper and sidewall surfaces of the contact hole.

### SUMMARY OF THE INVENTION

In one embodiment of the present invention, a method of cleaning a contact surface of an electronic device comprises positioning a substrate having an at least partially oxidized contact surface disposed thereon in a processing chamber, generating a reactive species from a gas mixture comprising nitrogen trifluoride and ammonia within the chamber, wherein the molar ratio of nitrogen trifluoride to ammonia is greater than about 2:1, directing the reactive species to the at least partially oxidized contact surface to react with the oxide thereon and form a film on the at least partially oxidized contact surface, and heating the substrate within the chamber to dissociate and remove the film.

In another embodiment, a method of cleaning a bottom surface of a contact hole comprises positioning a substrate having a contact hole with an oxidized bottom surface in a processing chamber, generating a reactive species from a gas mixture comprising nitrogen trifluoride, ammonia, and a carrier gas, wherein the molar ratio of nitrogen trifluoride to ammonia is greater than about 2:1, directing the reactive species to the bottom surface to react with the oxide thereon and form a film on the oxidized bottom surface, and heating the substrate within the chamber to dissociate and remove the film.

In yet another embodiment, a method of forming a metal contact comprises depositing a metal on a substrate in a first vacuum environment, annealing the substrate at conditions sufficient to provide a metal silicide layer, depositing an insulating cover layer on the metal silicide layer, forming a contact hole in the insulating cover layer exposing a portion of the metal silicide layer, transferring the substrate from the first vacuum environment to a second vacuum environment, wherein the exposed portion of the metal silicide layer at least partially oxidizes during the transfer, and exposing the exposed portion of the at least partially oxidized silicide layer to a reactive species in the second vacuum environment to remove the at least partially oxidized silicide layer while substantially maintaining the shape of the contact hole.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a cross section view of an illustrative clean chamber 100 for removing native oxides from a contact surface according to the present invention.

FIG. 2 is a schematic top-view diagram of an illustrative multi-chamber processing system 200.

FIGS. 3A-3N are sectional schematic views of an illustrative fabrication sequence for forming an illustrative active electronic device, such as a MOSFET structure 300.

### DETAILED DESCRIPTION

As will be explained in greater detail below, a substrate having a contact surface at least partially disposed thereon is treated to remove metal oxides or other contaminants prior to contact level metallization. The term “contact surface” as used herein refers to a layer of material that includes a metal silicide that can form part of a gate electrode. In one or more embodiments, the metal silicide can be nickel silicide, cobalt silicide, titanium silicide or any combinations thereof. The metal silicide can also include tungsten, Ti/Co alloy silicide, Ti/Ni alloy silicide, Co/Ni alloy silicide and Ni/Pt silicide.

The term “substrate” as used herein refers to a layer of material that serves as a basis for subsequent processing operations and includes a “contact surface.” For example, the substrate can include one or more conductive metals, such as aluminum, copper, tungsten, or combinations thereof. The substrate can also include one or more nonconductive materials, such as silicon, silicon oxide, doped silicon, germanium, gallium arsenide, glass, and sapphire. The substrate can also include dielectric materials such as silicon dioxide, organosilicates, and carbon doped silicon oxides. Further, the substrate can include any other materials such as metal nitrides and metal alloys, depending on the application. In one or more embodiments, the substrate can form part of an interconnect feature such as a plug, via, contact, line, and wire.

Moreover, the substrate is not limited to any particular size or shape. The substrate can be a round wafer. The substrate can also be any polygonal, square, rectangular, curved or otherwise non-circular workpiece, such as a glass substrate used in the fabrication of flat panel displays.

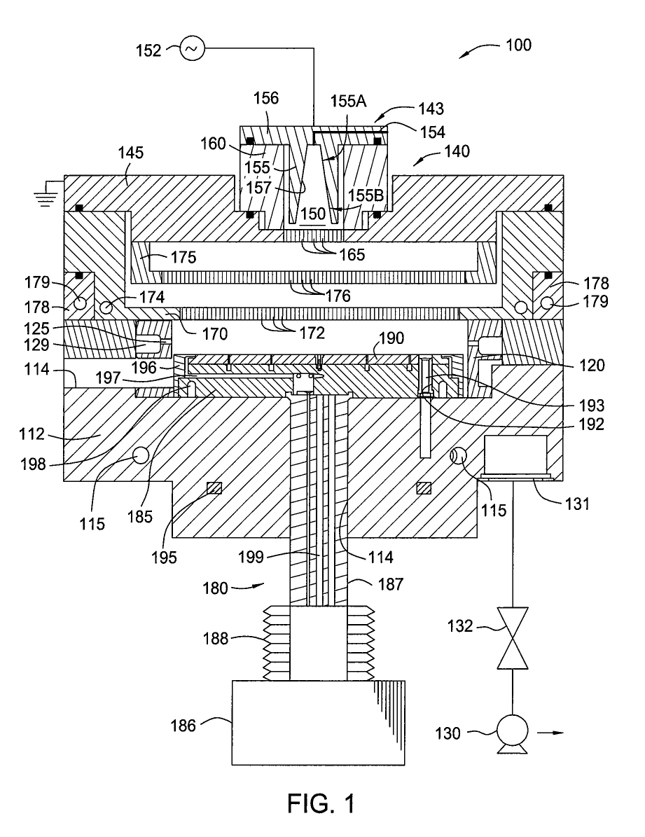

FIG. 1 is a cross sectional view of an illustrative clean chamber 100 for conducting bottom contact cleaning. The chamber 100 may be particularly useful for performing a plasma assisted dry etch process according to the present invention. The chamber 100 provides both heating and cooling of a substrate surface without breaking vacuum. In one embodiment, the chamber 100 includes a chamber body 112, a lid assembly 140, and a support assembly 180. The lid assembly 140 is disposed at an upper end of the chamber body 112, and the support assembly 180 is at least partially disposed within the chamber body 112.

The chamber body 112 includes a channel 115 formed therein for flowing a heat transfer fluid therethrough. The heat transfer fluid may be a heating fluid or a coolant and is used to control the temperature of the chamber body 112 during processing and substrate transfer. Exemplary heat transfer fluids include water, ethylene glycol, or a mixture thereof. An exemplary heat transfer fluid may also include nitrogen gas.

The chamber body 112 may further include a liner 120 that surrounds the support assembly 180. The liner 120 may be removable for servicing and cleaning. The liner 120 may be comprised of a metal such as aluminum, a ceramic material, or any other process compatible material. The liner 120 may be bead blasted to increase surface roughness and/or surface area to increase the adhesion of any material deposited thereon in order to prevent flaking and contamination of chamber 100. In one embodiment, the liner 120 includes one or more apertures 125 and a pumping channel 129 formed therein that is in fluid communication with a vacuum system. The apertures 125 provide a flow path for gases into the pumping channel 129, which provides an egress for the gases within the chamber 100.

The vacuum system may include a vacuum pump 130 and a throttle valve 132 to regulate flow of gases through the chamber 100. The vacuum pump 130 is coupled to a vacuum port 131 disposed on the chamber body 112 and in fluid communication with the pumping channel 129 formed within the liner 120. The terms “gas” and gases” are used interchangeably, unless otherwise noted and refer to one or more precursors, reactants, catalysts, carrier, purge, cleaning, and combinations thereof, as well as any other fluid introduced into the chamber body 112.

The lid assembly 140 includes at least two stacked components configured to form a plasma volume or cavity therebetween. In one embodiment, the lid assembly 120 includes a first electrode 143 disposed vertically above a second electrode 145 confining a plasma volume or cavity 150 therebetween. The first electrode 143 is connected to a power source 152, such as a radio frequency (RF) power supply, and the second electrode 145 is connected to ground, forming a capacitance between the two electrodes 143, 145.

In one embodiment, the lid assembly 140 includes one or more gas inlets 154 that are at least partially formed within an upper section 156 of the first electrode 143. The one or more process gases enter the lid assembly 140 via the one or more gas inlets 154. The one or more gas inlets 154 are in fluid communication with the plasma cavity 150 at a first end thereof and coupled to one or more upstream gas sources and/or other gas delivery components, such as gas mixers, at a second end thereof.

In one embodiment, the first electrode 143 has an expanding section 155 that houses the plasma cavity 150. In such embodiment, the expanding section 155 is an annular member with an inner surface 157 that gradually increases from an upper portion 155A to a lower portion 155B. As such, the distance between the first electrode 143 and the second electrode 145 is variable.

In one embodiment, the expanding section 155 resembles a cone or “funnel.” In another embodiment, the inner surface 157 of the expanding section 155 gradually slopes from the upper portion 155A to the lower portion 155B of the expanding section 155. The slope or angle of the inner surface 157 may vary depending on process requirements. The length or height of the expanding section 155 may also vary depending on specific process requirements.

The expanding section 155 is in fluid communication with the gas inlet 154. The first end of the one or more gas inlets 154 may open into the plasma cavity 150 at the upper most point of the inner diameter of the expanding section 155. Similarly, the first end of the one or more gas inlets 154 may open into the plasma cavity 150 at any height interval along the inner surface 157 of the expanding section 155. Although not shown, two gas inlets 154 may be disposed at opposite sides of the expanding section 155 to create a swirling flow pattern or “vortex” flow into the expanding section 155 which helps mix the gases within the plasma cavity 150.

The lid assembly 140 may include an isolator ring 160 to electrically isolate the first electrode 143 from the second electrode 145. The isolator ring 160 may be made from aluminum oxide or any other insulative, process compatible material. Preferably, the isolator ring 160 substantially surrounds at least the expanding section 155.

The lid assembly 140 may further include a distribution plate 170 and blocker plate 175 adjacent the second electrode 145. The second electrode 145, distribution plate 170 and blocker plate 175 may be stacked and disposed on a lid rim 178 which is connected to the chamber body 112. A hinge assembly (not shown) may be used to couple the lid rim 178 to the chamber body 112. The lid rim 178 may include an embedded channel or passage 179 for housing a heat transfer medium. The heat transfer medium may be used for heating, cooling, or both, depending on the process requirements.

In one embodiment, the second electrode 145 may include a plurality of gas passages or apertures 165 formed beneath the plasma cavity 150 to allow gas from the plasma cavity 150 to flow therethrough. The distribution plate 170 is substantially disc-shaped and also includes a plurality of apertures 172 or passageways to distribute the flow of gases therethrough. The apertures 172 may be sized and positioned about the distribution plate 170 to provide a controlled and even flow distribution to the chamber body 112, where the substrate to be processed is located. Furthermore, the apertures 172 prevent the gases from impinging directly on the substrate surface by slowing and re-directing the velocity profile of the flowing gases, as well as evenly distributing the flow of gases to provide an even distribution of gases across the surface of the substrate.

In one embodiment, the distribution plate 170 includes one or more embedded channels or passages 174 for housing a heater or heating fluid to provide temperature control of the lid assembly 140. A resistive heating element (not shown) may be inserted within the passage 174 to heat the distribution plate 170. A thermocouple may be connected to the distribution plate 170 to regulate the temperature thereof. The thermocouple may be used in a feedback loop to control electric current applied to the heating element.

Alternatively, a heat transfer medium may be passed through the passage 174. The one or more passages 174 may contain a cooling medium, if needed, to better control temperature of the distribution plate 170, depending on the process requirements within the chamber body 112. Any heat transfer medium may be used, such as nitrogen, water, ethylene glycol, or mixtures thereof, for example.

In one embodiment, the lid assembly 140 may be heated using one or more heat lamps (not shown). Typically, the heat lamps are arranged about an upper surface of the distribution plate 170 to heat the components of the lid assembly 140 including the distribution plate 170 by radiation.

An optional blocker plate 175 may be disposed between the second electrode 145 and the distribution plate 170. The blocker plate 175 may be removably mounted to a lower surface of the second electrode 145. The blocker plate 175 may be in thermal and electrical contact with the second electrode 145. In one embodiment, the blocker plate 175 may be coupled to the second electrode 145 using a bolt or similar fastener. The blocker plate 175 may also be threaded or screwed onto an outer diameter of the second electrode 145.

The blocker plate 175 includes a plurality of apertures 176 to provide a plurality of gas passages from the second electrode 145 to the distribution plate 170. The apertures 176 may be sized and positioned about the blocker plate 175 to provide a controlled and even flow distribution the distribution plate 170.

The support assembly 180 may include a support member 185 to support a substrate (not shown) for processing within the chamber body 112. The support member 185 may be coupled to a lift mechanism 186 through a shaft 187 which extends through a centrally-located opening 114 formed in a bottom surface of the chamber body 112. The lift mechanism 186 may be flexibly sealed to the chamber body 112 by a bellows 188 that prevents vacuum leakage from around the shaft 187. The lift mechanism 186 allows the support member 185 to be moved vertically within the chamber body 112 between a process position and a lower, transfer position. The transfer position is slightly below the opening 114 of the slit valve formed in a sidewall of the chamber body 112.

In one embodiment, the support member 185 has a flat, circular surface or a substantially flat, circular surface for supporting a substrate to be processed thereon. The support member 185 may be constructed of aluminum. The support member 185 may include a removable top plate 190 constructed of some other material, such as a ceramic material, for example, to reduce backside contamination of the substrate.

In one embodiment, the substrate (not shown) may be secured to the support member 185 using a vacuum chuck. In another embodiment, the substrate (not shown) may be secured to the support member 185 using an electrostatic chuck.

The support member 185 may include one or more bores 192 formed therethrough to accommodate a lift pin 193. Each lift pin 193 is typically constructed of ceramic or ceramic-containing materials and is used for substrate-handling and transport. The lift pin 193 is moveable within its respective bore 192 by engaging an annular lift ring 195 disposed within the chamber body 112. The lift ring 195 is movable such that the upper surface of the lift-pin 193 may be located above the substrate support surface of the support member 185 when the lift ring 195 is in an upper position. Conversely, the upper surface of the lift-pin 193 is located below the substrate support surface of the support member 185 when the lift ring 195 is in a lower position. Thus, part of each lift-pin 193 passes through its respective bore 192 in the support member 185 when the lift ring 195 moves from either the lower position to the upper position.

The support assembly 180 may further include an edge ring 196 disposed about the support member 185. In one embodiment, the edge ring 196 is an annular member that is adapted to cover an outer perimeter of the support member 185 and protect the support member 185 from deposition. The edge ring 196 may be positioned on, or adjacent to, the support member 185 to form an annular purge gas channel between the outer diameter of support member 185 and the inner diameter of the edge ring 196. The annular purge gas channel may be in fluid communication with a purge gas conduit 197 formed through the support member 185 and the shaft 187. The purge gas conduit 197 may be in fluid communication with a purge gas supply (not shown) to provide a purge gas to the purge gas channel. Any suitable purge gas such as nitrogen, argon, or helium, may be used alone or in combination. In operation, the purge gas flows through the conduit 197, into the purge gas channel, and about an edge of the substrate disposed on the support member 185. Accordingly, the purge gas working in cooperation with the edge ring 196 prevents deposition at the edge and/or backside of the substrate.

The temperature of the support assembly 180 may be controlled by a fluid circulated through a fluid channel 198 embedded in the body of the support member 185. In one embodiment, the fluid channel 198 is in fluid communication with a heat transfer conduit 199 disposed through the shaft 187 of the support assembly 180. The fluid channel 198 may be positioned about the support member 185 to provide a uniform heat transfer to the substrate receiving surface of the support member 185. The fluid channel 198 and heat transfer conduit 199 may flow heat transfer fluids to either heat or cool the support member 185. Any suitable heat transfer fluid may be used, such as water, nitrogen, ethylene glycol, or mixtures thereof. The support assembly 185 may further include an embedded thermocouple (not shown) for monitoring the temperature of the support surface of the support member 185. For example, a signal from the thermocouple may be used in a feedback loop to control the temperature or flowrate of the fluid circulated through the fluid channel 198.

The support member 185 may be moved vertically within the chamber body 112 so that a distance between support member 185 and the lid assembly 140 may be controlled. A sensor (not shown) may provide information concerning the position of support member 185 within chamber 100.

In operation, the support member 185 may be elevated to a position in close proximity of the lid assembly 140 to control the temperature of the substrate being processed. As such, the substrate may be heated via radiation emitted from the distribution plate 170. Alternatively, the substrate may be lifted from the support member 185 to a position in close proximity to the heated lid assembly 140 using the lift pins 193 activated by the lift ring 195.

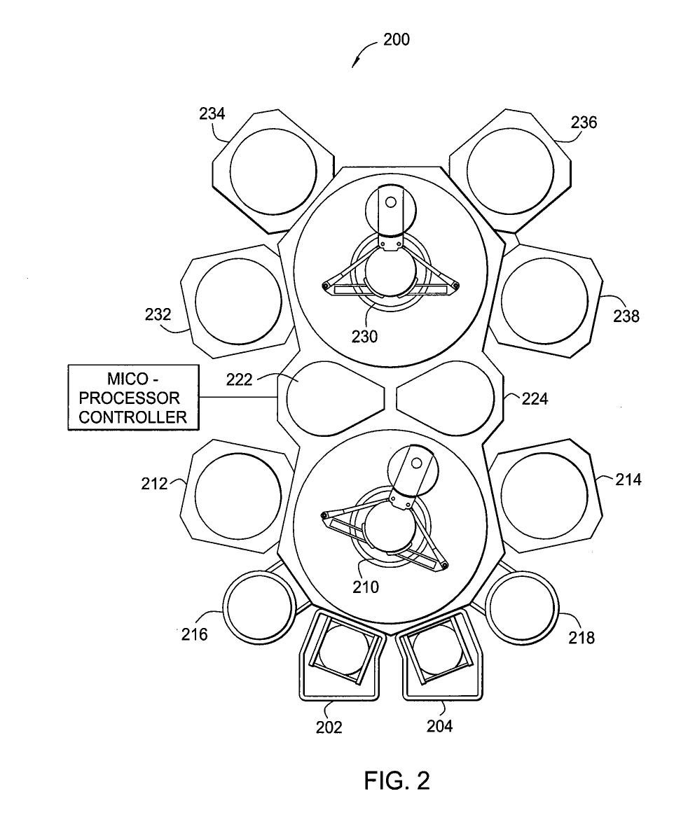

FIG. 2 is a schematic top-view diagram of an illustrative multi-chamber processing system 200 that may be adapted to perform processes as disclosed herein. The system 200 may include one or more load lock chambers 202, 204 for transferring substrates into and out of the system 200. A first robot 210 may transfer the substrates between the load lock chambers 202, 204, and a first set of substrate processing chambers 212, 214, 216, 218. Each processing chamber 212, 214, 216, 218, may be outfitted to perform a number of substrate processing operations including the dry etch processes described herein in addition to atomic layer deposition (ALD), chemical vapor deposition (CVD), physical vapor deposition (PVD), etch, pre-clean, and other substrate processes.

The first robot 210 may also transfer substrates to and from transfer chambers 222, 224. The transfer chambers 222, 224 may be used to maintain vacuum conditions while allowing substrates to be transferred within the system 200. A second robot 230 may transfer the substrates between the transfer chambers 222, 224 and a second set of processing chambers 232, 234, 236, 238. Similar to processing chambers 212, 214, 216, 218, the processing chambers 232, 234, 236, 238 may be outfitted to perform a variety of substrate processing operations. Any of the substrate processing chambers 212, 214, 216, 218, 232, 234, 236, 238 may be removed from the system 200 if not necessary for a particular process.

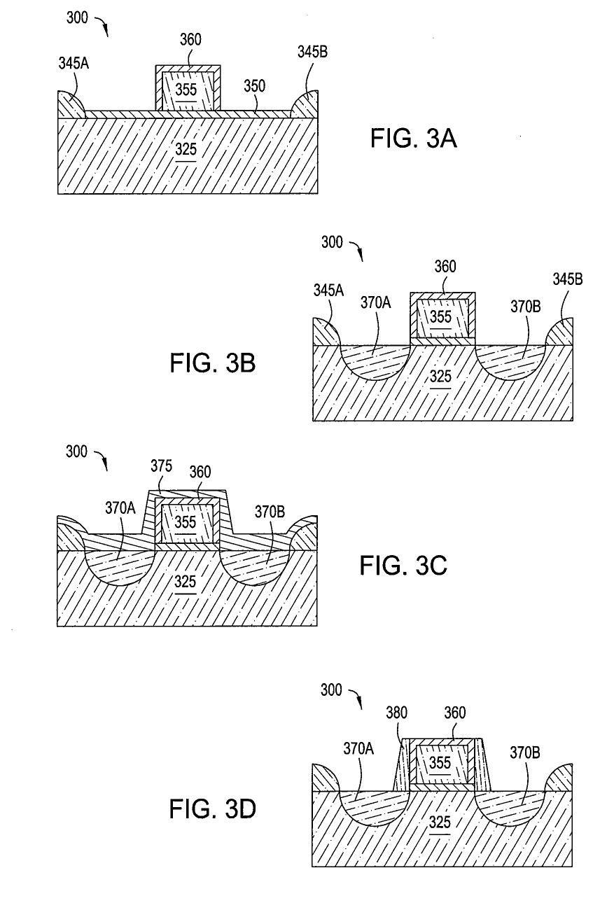

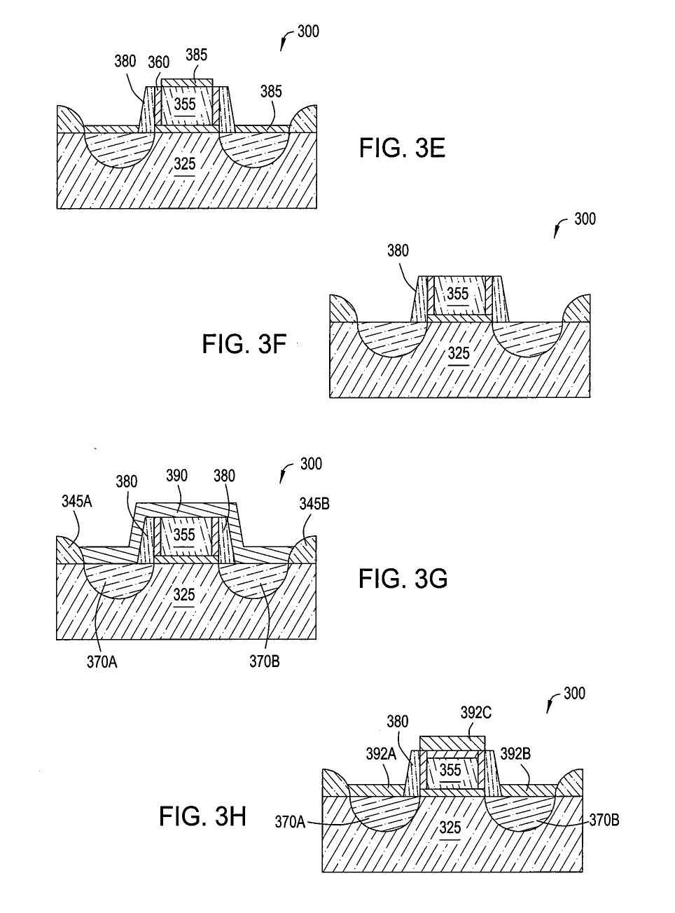

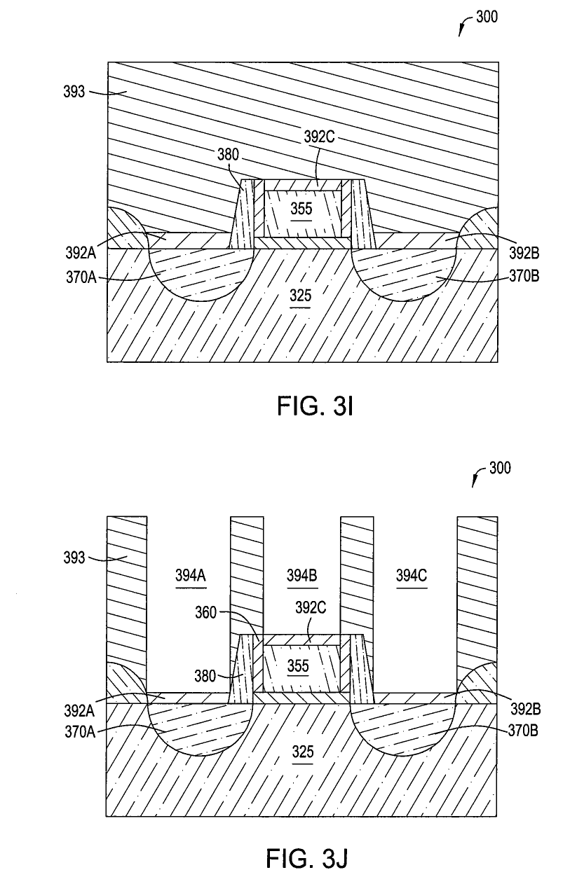

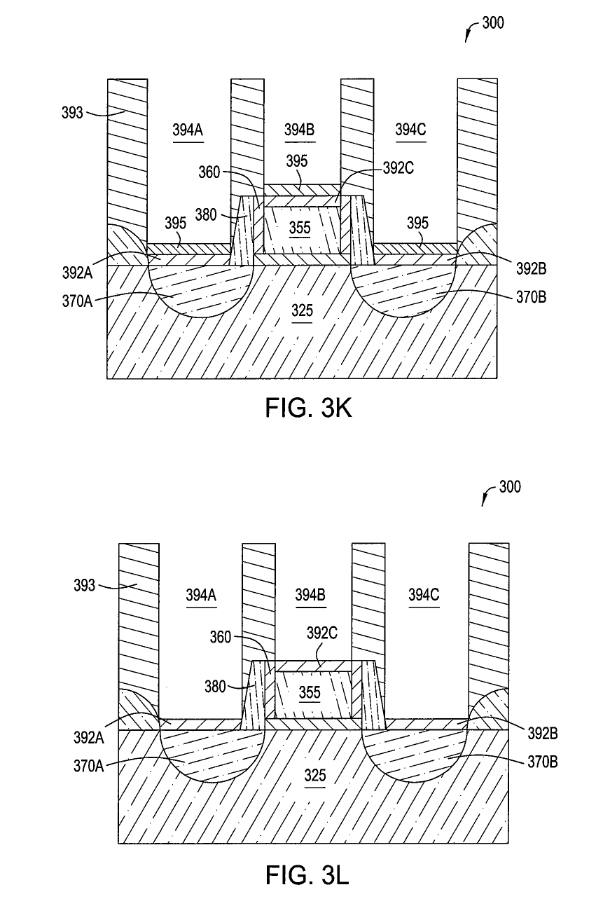

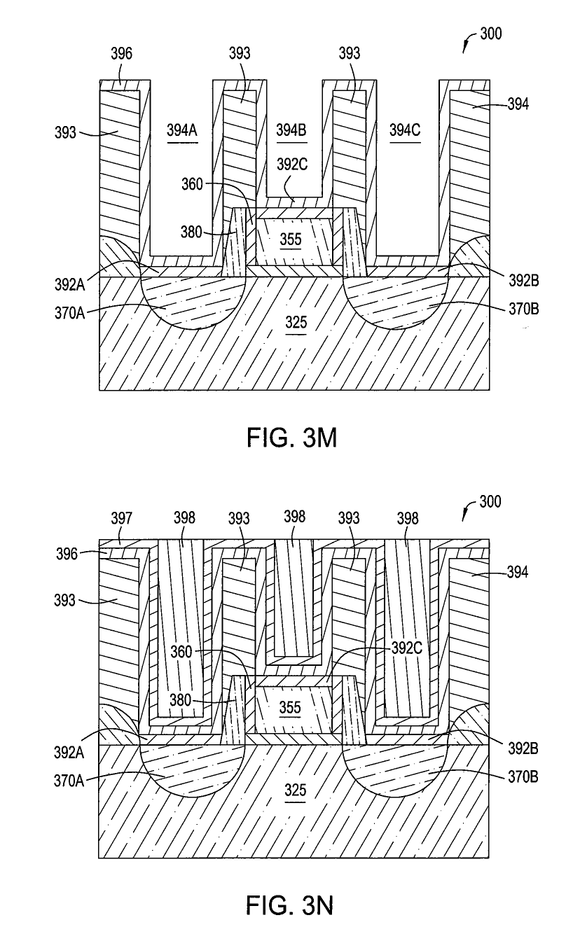

FIGS. 3A-3N are sectional schematic views of an illustrative fabrication sequence for forming an active electronic device, such as a MOSFET structure 300 using the bottom contact clean process described. The MOSFET structure 300 may include a combination of (i) dielectric layers, such as silicon dioxide, organosilicate, carbon doped silicon oxide, phosphosilicate glass (PSG), borophosphosilicate glass (BPSG), silicon nitride, or combinations thereof; (ii) semiconducting layers such as doped polysilicon, and n-type or p-type doped monocrystalline silicon; and (iii) electrical contacts and interconnect lines formed from layers of metal or metal silicide, such as tungsten, tungsten silicide, titanium, titanium silicide, cobalt silicide, nickel silicide, or combinations thereof. Each layer may be formed using any one or more depositions techniques, such as atomic layer deposition (ALD), physical vapor deposition (PVD), chemical vapor deposition (CVD), or plasma enhanced chemical vapor deposition (PECVD), for example.

Fabrication of the active electronic device begins by forming electrical isolation structures that electrically isolate the active electronic device from other devices. Several types of electrical isolation structures exist as generally described in VLSI Technology, Second Edition, Chapter 11, by S. M. Sze, McGraw-Hill Publishing Company (1988), which is incorporated herein by reference. Referring to FIGS. 3A-3N, the illustrative MOSFET structure 300 may be formed on a semiconductor material, for example a silicon or gallium arsenide substrate 325. A field oxide layer (not shown) having a thickness of about 2,000 Å is first grown over the entire substrate 325 and portions of the oxide layer are removed to form the field oxide barriers 345A, B which surround exposed regions in which the electrically active elements of the device are formed. The exposed regions are thermally oxidized to form a thin gate oxide layer 350 having a thickness of from about 50 to 300 Å. A polysilicon layer is then deposited, patterned, and etched to create a gate electrode 355. The surface of the polysilicon gate electrode 355 may be reoxidized to form an insulating dielectric layer 360.

Referring to FIG. 3B, the source and drain 370A, B may next be formed by doping the appropriate regions with one or more suitable dopant atoms. For example, on p-type substrates, an n-type dopant species comprising arsenic or phosphorous may be used. The doping may be performed by an ion implanter and may include, for example, phosphorous (³¹P) at a concentration of about 10¹³ atoms/cm² at an energy level of from about 30 to 80 Kev, or Arsenic (⁷⁵As) at a dose of from about 10¹⁵ to 10¹⁷ atoms/cm² and an energy of from 10 to 100 Kev. After the implantation process, the dopant may be driven into the substrate 325 by heating the substrate, for example, in a rapid thermal processing (RTP) apparatus. Thereafter, the oxide layer 350 (shown in FIG. 3A) covering the source and drain regions 370A, B may be stripped in a conventional stripping process to remove any impurities caused by the implantation process, which are trapped in the oxide layer.

Referring to FIGS. 3C and 3D, a silicon nitride layer 375 may be deposited on the gate electrode 355 and the surfaces on the substrate 325 by low-pressure chemical vapor deposition (LPCVD) using a gas mixture of SiH₂, Cl₂, and NH₃. The silicon nitride layer 375 may then be etched using reactive ion etching (RIE) techniques to form sidewall spacers 380 on the sidewall of the gate electrode 355, as shown in FIG. 3D. The electrical isolation sidewall spacers 380 and overlayers may be fabricated from other materials, such as silicon oxide. The silicon oxide layers used to form sidewall spacers 380 may be deposited by CVD or PECVD from a feed gas of tetraethoxysilane (TEOS) at a temperature in the range of from about 600° C. to about 1,000° C.

Referring to FIG. 3E, a native silicon oxide layer 385 may be formed on exposed silicon surfaces by exposure to atmosphere during transfer of the substrate 325 between processing chambers and/or processing systems. The native silicon oxide layer 385 may increase the electrical resistance of the semiconducting material and adversely affect the silicidation reaction of the silicon and metal layers that are subsequently deposited. Therefore, it is necessary to remove this native silicon oxide layer 385 prior to forming metal silicide contacts or conductors for interconnecting active electronic devices. A clean process, such as an NH₃/NF₃ clean process, as described in U.S. patent application Ser. No. 11/063,645 filed on February 22, 2005, which is herein incorporated by reference, may be used to remove the native silicon oxide layers 385 to expose the source 370A, drain 370B, and the top surface of the gate electrode 355 as shown in FIG. 3F.

Referring to FIG. 3G, a PVD sputtering process may be used to deposit a layer of metal 390. Suitable conductive metals include cobalt, titanium, nickel, tungsten, platinum, and any other metal that has a low contact resistance and that can form a reliable metal silicide contact on both polysilicon and monocrystalline silicon. Alloys or a combination of two or more metals may also be used.

Conventional furnace annealing may then be used to anneal the metal and silicon layers to form metal silicide in regions in which the metal layer 390 is in contact with silicon. The anneal is typically performed in a separate processing system. Accordingly, a protective cap layer (not shown) may be deposited over the metal 390 prior to the anneal step. The cap layer is typically of a nitride-containing material and can include titanium nitride, tungsten nitride, tantalum nitride, hafnium nitride, and silicon nitride. The cap layer may be deposited by any deposition process, such as by PVD. Annealing typically involves heating the substrate 325 to a temperature of between 500° C. and 800° C. in an atmosphere of nitrogen for about 30 minutes. Alternatively, a rapid thermal annealing process can be used in which the substrate 325 is rapidly heated to about 1,000° C. for about 30 seconds.

The cap layer and unreacted portions of the metal layer 390 may be removed by a wet etch using aqua regia, (HCl and HNO₃), which removes the metal without attacking the metal silicide, the sidewall spacer 380, or the field oxide 345A, B, thus leaving a self-aligned metal silicide contact 392A on the source 370A, a self-aligned metal silicide contact 392B on the drain 370B, and a self-aligned metal silicide contact 392C on the gate 355, as shown in FIG. 3H. The sidewall spacers 380 electrically isolate the metal silicide layer 392C formed on the top surface of the gate 355 from the other metal silicide layers 392A, 392B deposited over the source 370A and drain 370B.

Thereafter, an insulating cover layer 393 of, for example, silicon oxide, carbon doped silicon, BPSG, or PSG, may be deposited on the metal silicide 392A, 392B, 392C as shown in FIG. 3I. The insulating cover layer 393 may be deposited by chemical vapor deposition techniques in a CVD chamber, in which the material condenses from a feed gas at low or atmospheric pressure, as for example, described in commonly assigned U.S. Pat. No. 5,500,249, issued Mar. 19, 1996, which is incorporated herein by reference. Thereafter, the structure 300 is annealed at glass transition temperatures to form a smooth planarized surface.

The insulating cover layer 393 may then be etched to form contact holes 394A, 394B, 394C as shown in FIG. 3J. The structure 300 may then be transferred to a wet clean chamber to remove any etch residuals. As a result of this transfer, native oxides 395 may form on the contact surfaces 392A, 392B, 392C, as shown in FIG. 3K.

Next, the structure 300 may be subjected to a clean process to remove the native oxides 395 from metal silicide contact surfaces 392A, 392B, and 392C as shown in FIG. 3L. Preferably, the native oxides 395 are removed using a NF₃/NH₃ remote plasma process, which saturates at a low etch amount according to the present invention, to prevent over etching of the contact hole upper and sidewall surfaces while fully removing the native oxide from the bottom contact metal silicide surface. This process is described in greater detail as follows.

In one embodiment of this process, the structure 300 is first cooled below about 65° C., such as between about 15° C. and about 50° C. The structure 300 is preferably maintained below 50° C. In one embodiment, the structure 300 may be maintained at a temperature between about 22° C. (i.e. room temperature) and about 40° C. The nitrogen trifluoride (NF₃) and ammonia (NH₃) gases are then mixed to form a cleaning gas mixture. The amount of each gas introduced into the chamber 100 is variable and can be adjusted to accommodate, for example, the thickness of the oxide layer to be removed, the geometry of the structure being cleaned, the volume capacity of the plasma, the volume capacity of the chamber body, as well as the capabilities of the vacuum system coupled to the chamber body.

In one embodiment, the gases are added to provide a gas mixture having a greater concentration of nitrogen trifluoride than ammonia. Preferably, the gases are introduced into the chamber 100 at a molar ratio of from 1.1:1 (nitrogen trifluoride to ammonia) to about 30:1. More preferably, the molar ratio of the gas mixture is of from about 1.5:1 (nitrogen trifluoride to ammonia) to about 5:1. The molar ratio of the gas mixture may fall between 1.1:1 and 1.5:1. The molar ratio of the gas mixture may also fall between about 5:1 (nitrogen trifluoride to ammonia) and about 15:1.

A purge gas or carrier gas may also be added to the gas mixture. Any suitable purge/carrier gas may be used, such as argon, helium, hydrogen, nitrogen, or mixtures thereof. The overall gas mixture may be from about 0.05% to about 60% by volume of nitrogen trifluoride and ammonia. The remainder of the gas mixture is the purge/carrier gas. In one embodiment, the purge/carrier gas is first introduced into the chamber body 112 before the reactive gases to stabilize the pressure within the chamber body 112.

The operating pressure within the chamber 100 may be variable. The pressure may be maintained between about 500 mTorr and about 30 Torr. Preferably, the pressure is maintained between about 1 Torr and about 10 Torr. More preferably, the operating pressure is maintained between about 3 Torr and about 7 Torr.

An RF power between about 5 and about 600 Watts is preferred to ignite a plasma of the gas mixture. Preferably, the RF power is less than about 100 Watts. More preferably, RF power is between about 50 Watts and about 70 Watts.

The plasma energy dissociates the nitrogen trifluoride and ammonia gases into reactive species, e.g. fluorine radicals and/or hydrogen radicals, that combine to form a highly reactive ammonia fluoride (NH₄F) compound and/or ammonium hydrogen fluoride (NH₄F.HF) in the gas phase. These molecules are then delivered from the remote plasma location to the surface to be cleaned where they combine with the oxide to form a thin, by-product film. The thin, by-product film may be a salt comprising nitrogen and fluorine atoms. In one embodiment, the thin, by-product film may be ammonium hexafluorosilicate (NH₄)₂SiF₆. A purge/carrier gas may be used to facilitate the delivery of the reactive species to the surface.

After the thin film is formed on the surface, the surface is annealed to remove the thin film. The anneal temperature should be sufficient to dissociate or sublimate the thin film into volatile ammonia and fluorine-containing products. Typically, a temperature of about 75° C. or more is used to effectively dissociate and remove the thin film from the substrate. Preferably, a temperature of about 100° C. or more is used, such as between about 115° C. and about 200° C.

This oxide removal process has a very low etch saturation point. That is, the etch reaction is completed at a very low etch amount, such as 20-50 Å. Accordingly, the etch at the upper and sidewall surfaces of the contact hole saturates very quickly, while the bottom contact etch completes the native oxide removal. Therefore, unlike previous recipes, the upper surfaces of the contact opening are minimally affected, while the bottom contact is optimally cleaned. This improved process results in an electronic device with decreased contact resistance and minimal leakage current.

Thereafter, the cleaned structure 300 may be treated with a silicon-containing compound to recover the metal silicide contact surface 392A, 392B, 392C.

After the metal silicide contact surface 392A, 392B, 392C has been recovered, one or more liner or barrier layers 396 may be deposited on the substrate, as shown in FIG. 3M. The barrier layer 396 may contain any one or more refractory metals deposited by any deposition technique capable of providing good step coverage. For example, the barrier layer 396 may include titanium, tantalum, or tungsten deposited by one or more physical vapor deposition techniques. The barrier layer 396 may also include one or more refractory metal nitrides.

In one embodiment, a first layer 396 (i.e. “liner” layer) containing a refractory metal may be deposited followed by a second layer 397 (i.e. “barrier” layer) containing a refractory metal nitride, as shown in FIG. 3N. For example, a titanium liner layer may be deposited followed by a titanium nitride layer. In either layer, the refractory metal may be tantalum or tungsten in lieu of or in addition to titanium.

Thereafter, the contact holes 394A, 394B, 394C are at least partially filled with a bulk metal layer 398, as shown in FIG. 3N. Illustrative metals include, but are not limited to, copper, tungsten, titanium, and tantalum.

Although the process sequence above has been described in relation to the formation of a MOSFET device, the etch process described may also be used to form other semiconductor structures and devices that have other metal silicide layers, for example, silicides of tungsten, tantalum, molybdenum. The cleaning process can also be used prior to the deposition of layers of different metals including, for example, aluminum, copper, cobalt, nickel, silicon, titanium, palladium, hafnium, boron, tungsten, tantalum, or mixtures thereof. Further, the cleaning process can be used to remove oxides formed on a substrate surface in addition to native oxides. For example, oxides may result due to chemical etch processes performed on the substrate, photoresist strip processes performed on the substrate, wet clean processes, and any other oxygen based process.

While the foregoing is directed to embodiments of the present invention, other and further embodiments of the invention may be devised without departing from the basic scope thereof, and the scope thereof is determined by the claims that follow.

1. A method of cleaning a contact surface of an electronic device, comprising:
positioning a substrate having an at least partially oxidized contact surface disposed thereon in a processing chamber;
generating a reactive species from a gas mixture comprising nitrogen trifluoride and ammonia within the chamber, wherein the concentration of nitrogen trifluoride is greater than the concentration of ammonia;
directing the reactive species to the at least partially oxidized contact surface to react with the oxide thereon and form a film on the at least partially oxidized contact surface; and
heating the substrate within the chamber to dissociate and remove the film.

2. The method of claim 1, further comprising cooling the substrate prior to the generating a reactive species.

3. The method of claim 2, wherein cooling the substrate comprises maintaining a substrate temperature below about 25° C.

4. The method of claim 1, wherein heating the substrate comprises maintaining the substrate temperature above 75° C.

5. The method of claim 1, wherein the molar ratio of nitrogen trifluoride to ammonia is between about 1.5:1 and about 10:1.

6. The method of claim 1, wherein the film is a salt comprising nitrogen and fluorine atoms.

7. A method of cleaning a bottom surface of a contact hole, comprising:
positioning a substrate having a contact hole with an oxidized bottom surface in a processing chamber;
generating a reactive species from a gas mixture comprising nitrogen trifluoride, ammonia, and a carrier gas, wherein the molar ratio of nitrogen trifluoride to ammonia is greater than about 1.5:1;
directing the reactive species to the bottom surface to react with the oxide thereon and form a film on the oxidized bottom surface; and
heating the substrate within the chamber to dissociate and remove the film.

8. The method of claim 7, wherein the molar ratio of nitrogen trifluoride to ammonia is between about 1.5:1 and about 10:1.

9. The method of claim 7, wherein the gas mixture comprises between about 10% to about 60% by volume of nitrogen trifluoride and ammonia.

10. The method of claim 7, wherein the carrier gas is helium.

11. The method of claim 7, wherein the gas mixture comprises greater than about 50% by volume of carrier gas.

12. The method of claim 7, wherein heating the substrate comprises maintaining the substrate temperature above about 100° C.

13. The method of claim 7, wherein the film is a salt comprising nitrogen and fluorine atoms.

14. The method of claim 7, further comprising cooling the substrate prior to the generating a reactive species.

15. The method of claim 14, wherein the cooling the substrate comprises maintaining the substrate below room temperature.

16-20. (canceled)

21. A method of cleaning a contact surface, comprising:
positioning a substrate in a processing chamber, wherein the substrate has a metal silicide layer with an at least partially oxidized contact surface thereon;
generating an active species from a gas mixture comprising nitrogen trifluoride and ammonia within the chamber, wherein the molar ratio of nitrogen trifluoride to ammonia is between about 1.5:1 and about 10:1;
directing the reactive species to the at least partially oxidized contact surface to react with the oxide thereon and form a film on the at least partially oxidized contact surface; and
heating the substrate to above about 75° C. within the chamber to dissociate and remove the film.

22. The method of claim 21, further comprising cooling the substrate prior to generating a reactive species.

23. The method of claim 22, wherein cooling the substrate comprises maintaining a substrate temperature below about 25° C.

24. The method of claim 23, wherein the film is a salt comprising nitrogen and fluorine atoms.

25. The method of claim 24, wherein heating the substrate comprises maintaining the substrate temperature above 100° C.
